(19) United States
(12) Patent Application Publication
(10) Pub. No.: US 2026/0333864 A1
(43) Pub. Date: Oct. 22, 2026

(54) SEMICONDUCTOR DEVICE WITH EPITAXIAL PATTERNS

(71) Applicant: Samsung Electronics Co., Ltd., Suwon-si (KR)

(72) Inventors: Gibum Kim, Suwon-si (KR); Geunsoo Yang, Suwon-si (KR)

(21) Appl. No.: 19/637,707

(22) Filed: Apr. 2, 2026

(30) Foreign Application Priority Data
Apr. 18, 2025 (KR) 10-2025-0051049

(51) Int. Cl. H10D 86/00; H10D 30/00; H10D 30/43; H10D 62/10; H10D 62/13; H10D 64/23; H10D 64/27; H10W 20/41; H10W 20/43

(52) U.S. Cl. CPC H10D 86/201; H10D 30/503; H10D 30/506; H10D 62/151; H10D 64/256; H10D 64/518; H10W 20/43; H10W 20/435; H10D 30/43; H10D 62/121; H10W 20/427

(57) ABSTRACT

A semiconductor device includes first and second active patterns extending on an insulating base layer, an inactive gate structure crossing the first and second active patterns, a first P-type epitaxial pattern and a second P-type epitaxial pattern respectively disposed on first and second sides of the inactive gate structure opposing each other, a first N-type epitaxial pattern and a second N-type epitaxial pattern respectively disposed on the first and second sides of the inactive gate structure opposing each other, a shared contact connecting the first P-type epitaxial pattern and the first N-type epitaxial pattern to each other, on the first side of the inactive gate structure, and a first contact and a second contact respectively connected to the second P-type epitaxial pattern and the second N-type epitaxial pattern, on the second side of the inactive gate structure.

### CROSS-REFERENCE TO RELATED APPLICATION(S)

This application claims benefit of priority to Korean Patent Application No. 10-2025-0051049 filed on Apr. 18, 2025 in the Korean Intellectual Property Office, the entirety of which is incorporated herein by reference.

### BACKGROUND

As demand for implementation of high performance, high speed, and/or multifunctionality of semiconductor devices increases, a degree of integration of semiconductor devices has been increasing. In order to overcome a limitation of operating properties due to a reduction in the size of a planar metal oxide semiconductor FET (MOSFET), efforts have been made to develop a semiconductor device including a gate-all-around-type field effect transistor including a finFET including a fin-type channel and nanosheets surrounded by a gate.

### SUMMARY

Some aspects of the present disclosure provide semiconductor devices having improved electrical characteristics and reliability.

According to some implementations of the present disclosure, there is provided a semiconductor device including an insulating base layer having a first surface and a second surface opposite to each other, first and second active patterns extending on the first surface of the insulating base layer in a first direction, an inactive gate structure crossing the first and second active patterns in a second direction, intersecting the first direction, a first P-type epitaxial pattern and a second P-type epitaxial pattern respectively disposed on regions of the first active pattern, on first and second sides of the inactive gate structure opposing each other, a first N-type epitaxial pattern and a second N-type epitaxial pattern respectively disposed on regions of the second active pattern, on the first and second sides of the inactive gate structure opposing each other, a shared contact connecting the first P-type epitaxial pattern and the first N-type epitaxial pattern to each other, on the first side of the inactive gate structure, and a first contact and a second contact respectively connected to the second P-type epitaxial pattern and the second N-type epitaxial pattern, on the second side of the inactive gate structure.

According to some implementations of the present disclosure, there is provided a semiconductor device including an insulating base layer having a first surface and a second surface opposite to each other, first and second active patterns extending on the first surface of the insulating base layer in a first direction, first and second inactive gate structures crossing the first and second active patterns in a second direction, intersecting the first direction, a P-type epitaxial pattern disposed on a region of the first active pattern, between the first and second inactive gate structures, an N-type epitaxial pattern disposed on a region of the second active pattern, between the first and second inactive gate structures, an interlayer insulating layer disposed on the first surface of the insulating base layer, the interlayer insulating layer covering the P-type epitaxial pattern and the N-type epitaxial pattern, a shared contact connecting the P-type epitaxial pattern and the N-type epitaxial pattern to each other, between the first and second inactive gate structures, a first contact connected to the P-type epitaxial pattern, between the first and second inactive gate structures, and a second contact connected to the N-type epitaxial pattern, between the first and second inactive gate structures.

According to some implementations of the present disclosure, there is provided a semiconductor device including an insulating base layer having a first surface and a second surface opposite to each other, a first active pattern and a second active pattern extending on the first surface of the insulating base layer in a first direction, a first inactive gate structure and a second inactive gate structure crossing the first and second active patterns in a second direction, intersecting the first direction, a first P-type epitaxial pattern and a first N-type epitaxial pattern respectively disposed in regions of the first and second active patterns, between one sides of the first and second inactive gate structures, a second P-type epitaxial pattern and a second N-type epitaxial pattern respectively disposed in the regions of the first and second active patterns, on the other side of the first inactive gate structure, a third P-type epitaxial pattern and a third N-type epitaxial pattern respectively disposed in the regions of the first and second active patterns, on the other side of the second inactive gate structure, an interlayer insulating layer disposed on the first surface of the insulating base layer, the interlayer insulating layer covering the first to third P-type epitaxial patterns and the first to third N-type epitaxial patterns, a first contact and a second contact respectively connected to the first P-type epitaxial pattern and the first N-type epitaxial pattern, between the one sides of the first and second inactive gate structures, a first shared contact connecting the second P-type epitaxial pattern and the second N-type epitaxial pattern to each other, on the other side of the first inactive gate structure, and a second shared contact connecting the third P-type epitaxial pattern and the third N-type epitaxial pattern to each other, on the other side of the second inactive gate structure.

### BRIEF DESCRIPTION OF DRAWINGS

The above and other aspects, features, and advantages provided by the present disclosure will be more clearly understood from the following detailed description, taken in conjunction with the accompanying drawings, in which:

FIG. 1 is a plan view of two regions of an example of a semiconductor device;

FIG. 2 is a cross-sectional view of a first element region A of the semiconductor device of FIG. 1, taken along I-I′;

FIGS. 3A and 3B are cross-sectional views of the first region A of the semiconductor device of FIG. 1, taken along II1-II1′ and II2-II2′;

FIGS. 4A, 4B, and 4C are cross-sectional views of a second region B of the semiconductor device of FIG. 1, taken along III1-III1′, III2-III2′, and III3-III3′;

FIG. 5 is a graph illustrating examples of IV characteristics of a circuit element of a semiconductor device;

FIGS. 6A and 6B are a schematic block diagram and circuit diagram, respectively, illustrating an operating principle of a circuit element;

FIG. 7 is a plan view of an example of a semiconductor device;

FIGS. 8A and 8B are cross-sectional views of the semiconductor device of FIG. 7, taken along III1-III1′ and III2-III2′;

FIG. 9 is a plan view of an example of a semiconductor device;

FIGS. 10A and 10B are cross-sectional views of the semiconductor device of FIG. 9, taken along III1-III1′ and III2-III2′;

FIG. 11 is a plan view of an example of a semiconductor device;

FIGS. 12A and 12B are cross-sectional views of the semiconductor device of FIG. 11, taken along III1-III1′ and III2-III2′;

FIG. 13A is a plan view of an example of a semiconductor device;

FIG. 13B is a cross-sectional view of the semiconductor device of FIG. 13A, taken along III1-III1′;

FIG. 14A is a plan view of an example of a semiconductor device;

FIG. 14B is a cross-sectional view of the semiconductor device of FIG. 14A, taken along line III1-III1′;

FIG. 15 is a plan view of an example of a semiconductor device.

### DETAILED DESCRIPTION

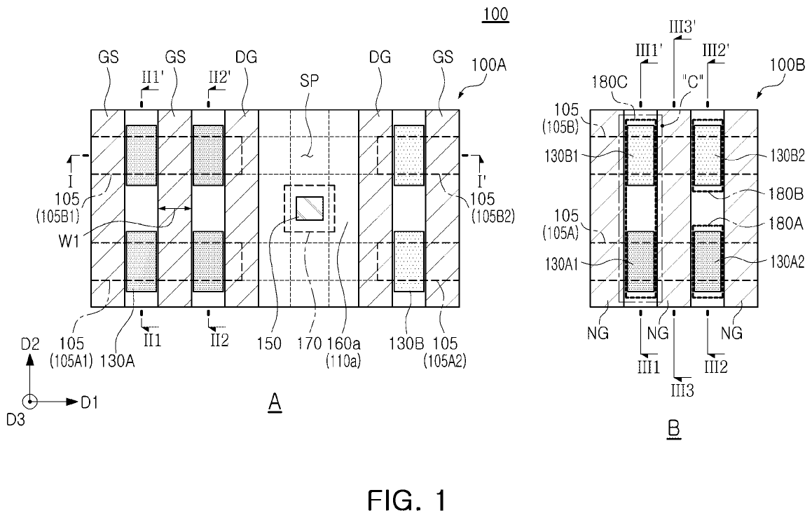

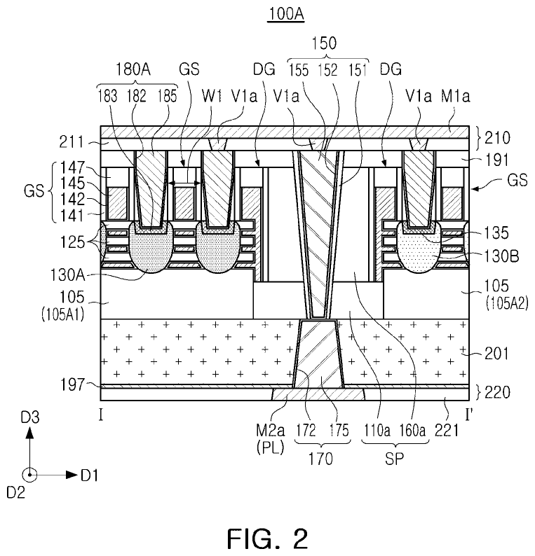

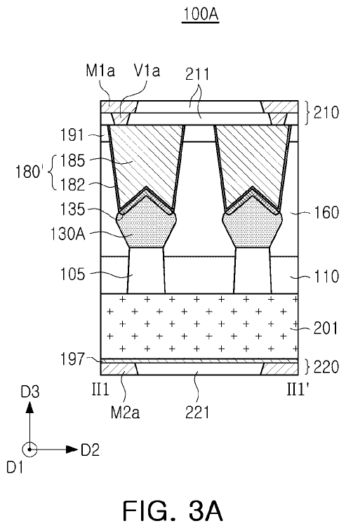

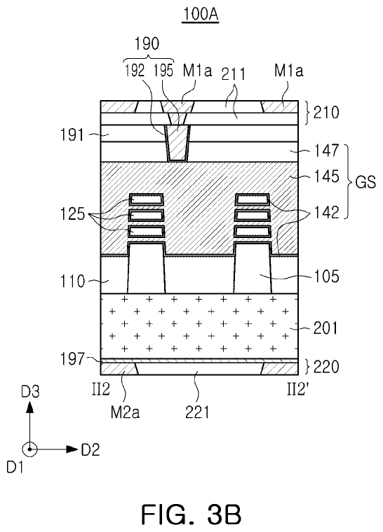

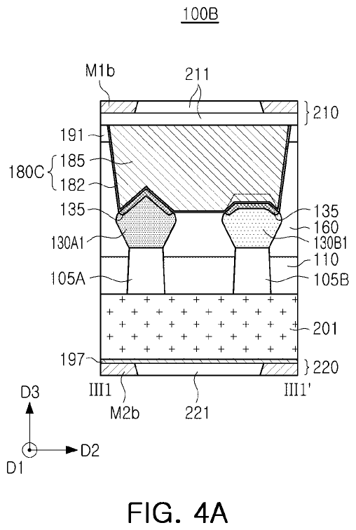

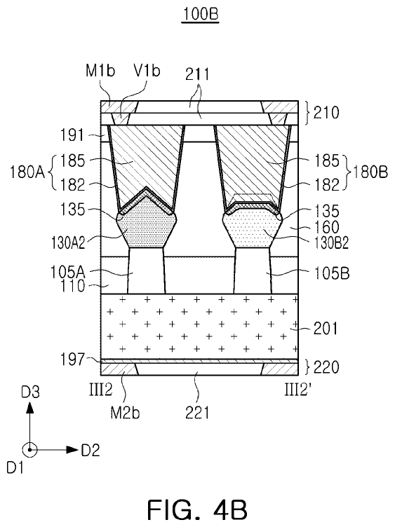

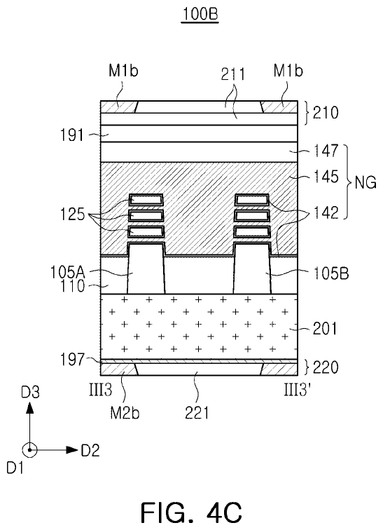

FIG. 1 is a plan view of an example of a semiconductor device. FIG. 2 is a cross-sectional view of a first element region A of the semiconductor device of FIG. 1, taken along I-I′, and FIGS. 3A and 3B are cross-sectional views of the first region A of the semiconductor device of FIG. 1, taken along II1-II1′ and II2-II2′. FIGS. 4A to 4C are cross-sectional views of a second region B of the semiconductor device of FIG. 1, taken along III1-III1′, III2-III2′, and III3-III3′.

First, referring to FIG. 1, a semiconductor device 100 may include a first region A and a second region B arranged in a horizontal direction (for example, a D1 direction and/or a D2 direction). Here, the first region A may also be referred to as a “logic region” in which logic elements 100A are formed, and the second region B may also be referred to as a “peripheral circuit region” in which peripheral circuit elements 100B are formed.

Referring to FIGS. 2, 3A, and 3B together with FIG. 1, a logic element 100A of the semiconductor device 100 may include an insulating base layer 201, a plurality of active patterns 105 extending on the first region A of the insulating base layer 201 in the first direction (for example, a D1 direction), and a separation pattern SP extending in a second direction (for example, a D2 direction), intersecting the first direction (for example, a D1 direction), the separation pattern SP separating each of the plurality of active patterns 105 into first and second active patterns 105A1, 105B1, 105A2, and 105B2.

The semiconductor device 100 may include gate structures GS respectively crossing the plurality of active patterns 105, the gate structures GS extending in the second direction (for example, a D2 direction), and a dummy gate structure DG extending in the second direction (for example, a D2 direction) along ends of the plurality of active patterns 105, on both sides of the separation pattern SP. Here, the gate structure GS may be referred to as an “active gate structure” included in a transistor, and the dummy gate structure DG may be referred to as an “inactive gate structure” not included in the transistor.

In some implementations, as in the example of FIG. 1, it is illustrated that a P-MOS transistor is disposed on a left side of the separation pattern SP, and an N-MOS transistor is disposed on a right side of the separation pattern SP.

The P-MOS transistor may further include first source/drain patterns 130A disposed on the first active patterns 105A1 and 105B1, on both sides of the gate structure GS, and the first source/drain patterns 130A may include a P-type epitaxial layer. The N-MOS transistor may further include second source/drain patterns 130B disposed on the second active patterns 105A2 and 105B2, on both sides of the gate structure GS, and the second source/drain patterns 130B may include an N-type epitaxial layer.

The insulating base layer 201 may include an insulating material layer prepared after removing a semiconductor substrate used to form the elements (for example, 100A and 100B). In some implementations, the insulating base layer 201 may include an oxide layer. For example, the insulating base layer 201 may include flowable oxide (FOX), Tonen SilaZen (TOSZ), undoped silica glass (USG), borosilica glass (BSG), phosphosilica glass (PSG), borophosphosilica glass (BPSG), plasma enhanced tetraethyl orthosilicate (PETEOS), fluoride silicate glass (FSG), high density plasma oxide (HDP oxide), plasma enhanced oxide (PEOX), flowable chemical vapor deposition oxide (FCVD oxide), or combinations thereof. The insulating base layer 201 may be formed using a chemical vapor deposition (CVD) process, a flowable-CVD process, or a spin coating process.

The active patterns 105 may have a fin-type structure protruding in a third direction (for example, a D3 direction) on the insulating base layer 201 and extending in the first direction (for example, a D1 direction). The active patterns 105 may be patterns obtained by partially etching the semiconductor substrate. In some implementations, the active patterns 105 may have a structure obtained by removing a portion of the semiconductor substrate below the active patterns 105. Accordingly, the active patterns 105 may include a semiconductor material the same as that of the semiconductor substrate. For example, the active patterns 105 may include a semiconductor such as Si or Ge, or a compound semiconductor such as SiGe, SiC, GaAs, InAs or InP.

An isolation layer 110 may be disposed on an insulating base layer 201, and may define an active pattern 105. For example, the isolation layer 110 may include silicon oxide or a silicon oxide-based insulating material. The isolation layer 110 may be a trench isolation defining the active pattern 105.

Referring to FIGS. 1, 2, 3A, and 3B, active patterns 105 may have a fin-type structure extending in the first direction (for example, a D1 direction) on a first surface (that is, an upper surface) of the insulating base layer 201. A plurality of semiconductor patterns 125 may be disposed on a region of the active patterns 105 to be spaced from each other in a direction perpendicular to the first surface of the insulating base layer 201, that is, in the third or vertical direction (for example, a D3 direction). The plurality of semiconductor patterns 125 may be provided as a multi-channel region of each transistor. Three semiconductor patterns 125 are illustrated, but the number thereof is not limited to three. For example, the plurality of semiconductor patterns 125 may include silicon (Si) or silicon germanium (SiGe).

The logic element 100A may include a plurality of gate structures GS extending in the second direction (for example, a D2 direction), as illustrated in FIG. 1. As described above, the plurality of gate structures GS may be arranged to intersect first and second active patterns 105A1 and 105B1 and 105A2 and 105B2 separated by the separation pattern SP in the first direction (for example, a D1 direction).

Referring to FIGS. 2, 3A, and 3B, each of the gate structures GS may include gate spacers 141, a gate insulating film 142 and a gate electrode 145 sequentially disposed between the gate spacers 141, and a gate capping layer 147 disposed on the gate electrode 145. For example, the gate spacers 141 may include an insulating material such as SiOCN, SiON, SiCN, or SiN. The gate insulating film 142 may be formed of, for example, a silicon oxide film, a high-κ dielectric film, or a combination thereof. The high-κ dielectric film may include a material having a dielectric constant (for example, about 10 to 25) higher than that of the silicon oxide film. For example, the high-κ dielectric film may include a material selected from hafnium oxide, hafnium oxynitride, hafnium silicon oxide, lanthanum oxide, lanthanum aluminum oxide, and combinations thereof, but the material is not limited thereto. The gate electrode 145 may include a conductive material, and may include, for example, a metal nitride such as a titanium nitride (TiN) film, a tantalum nitride (TaN) film, or a tungsten nitride (WN) film, and/or a metal material such as aluminum (Al), tungsten (W), or molybdenum (Mo) or a semiconductor material such as doped polysilicon. In some implementations, the gate electrode 145 may be a multilayer including two or more films. The gate capping layer 147 may include, for example, silicon nitride, silicon oxynitride, silicon carbonitride, or silicon oxycarbonitride.

The logic element 100A may include a power transfer structure arranged according to the separation pattern SP, the power transfer structure configured to supply power to each transistor cell from a second surface (e.g., a lower surface) of the insulating base layer 201. The power transfer structure may include a buried conductive structure 150 arranged on the separation pattern SP in the second direction (for example, a D2 direction), and conductive via structures 170 extending from the second surface of the insulating base layer 201 toward the first surface, the and conductive via structures 170 connected to the buried conductive structure 150.

In some implementations, as illustrated in FIG. 2, the buried conductive structures 150 may extend to the first surface of the insulating base layer 201, and the conductive via structure 170 may pass through the insulating base layer 201 to be in contact with bottom surfaces of the buried conductive structures 150 on the first surface of the insulating base layer 201. The conductive via structures 170 may receive power from a second interconnection line M2a positioned on the second surface of the insulating base layer 201 and may supply power to first and second source/drain patterns 130A and 130B of the logic element 100A through the buried conductive structures 150. In some implementations, the buried conductive structures 150 may be electrically connected to the first and second source/drain patterns 130A and 130B through a first interconnection line M1a that is a power line of a first interconnection structure 210.

The buried conductive structure 150 may include a conductive material 155 and a conductive barrier 152 surrounding a bottom surface and a side surface of the conductive material 155. In some implementations, the buried conductive structure 150 may further include an insulating liner 151 surrounding the conductive barrier 152. The conductive via structure 170 may include a conductive material 175 and a conductive barrier 172 surrounding a bottom surface and a side surface of the conductive material 175.

For example, the conductive materials 155 and 175 may include Cu, Co, Mo, Ru, W, or alloys thereof. In some implementations, the conductive materials 155 and 175 may include different conductive materials. For example, the conductive barriers 152 and 172 may include Ta, TaN, Mn, MnN, WN, Ti, TiN, or combinations thereof. For example, the insulating liner 151 may include SiO₂, SiN, SiCN, SiC, SiCOH, SiON, Al₂O₃, AlN, or combinations thereof.

In some implementations, the dummy gate structures DG, positioned on both sides of the separation pattern SP, may include components similar to those of the gate structure GS. Each of the dummy gate structures DG may include gate spacers 141, a gate insulating film 142, a gate electrode 145, and a gate capping layer 147. However, as described above, the dummy gate structures DG may be positioned on ends of the first and second active patterns 105A1 and 105B1 and 105A2 and 105B2, such that portions of the dummy gate structures DG may extend to the isolation layer 110a along cross-sections of the first and second active patterns 105A1 and 105A2, as illustrated in FIG. 2.

The first and second source/drain patterns 130A and 130B may be disposed on regions of the first and second active patterns 105A1 and 105B1 and 105A2 and 105B 2 positioned on both sides of the gate structure GS. The first and second source/drain patterns 130A and 130B may be respectively connected to both ends of the plurality of semiconductor patterns 125 in the first direction (for example, a D1 direction). The gate electrode 145 may have a portion extending in the second direction (for example, a D2 direction) to intersect the first and second active patterns 105A1 and 105B1 and 105A2 and 105B2 while surrounding the plurality of semiconductor patterns 125. The gate insulating film 142 may also have a portion extending to a space between the plurality of semiconductor patterns 125 and the extending portion of the gate electrode 145. As described, the logic element 100A of the semiconductor device 100 may form a gate-all-around (GAA) type field-effect transistor.

The first and second source/drain patterns 130A and 130B may include epitaxial patterns selectively epitaxially grown (e.g., by selective epitaxial growth (SEG)) from recessed surfaces of the first and second active patterns 105A1 and 105B1 and 105A2 and 105B2 and from side surfaces of the plurality of semiconductor patterns 125, on both sides of the gate structure GS. For example, the first and second source/drain patterns 130A and 130B may be Si, SiGe, or Ge, and may have one of an N-type or a P-type conductivity. In some implementations, when the first source/drain patterns 130A are P-type epitaxial patterns, the first source/drain patterns 130A may include silicon (Si) or silicon germanium (SiGe) doped with a P-type impurity such as boron (B), indium (In), gallium (Ga), and/or boron trifluoride (BF₃). In addition, when the second source/drain patterns 130B are N-type epitaxial patterns, the second source/drain patterns 130B may include silicon (Si) doped with an N-type impurity such as phosphorus (P), nitrogen (N), arsenic (As), and/or antimony (Sb).

The first and second source/drain patterns 130A and 130B may have different shapes along a crystallographically stable surface during the growth process. For example, the P-type first source/drain patterns 130A may have a pentagonal cross-section (see FIG. 3A), and the N-type second source/drain patterns 130B may have a hexagonal or polygonal cross-section having a gentle angle.

As described above, the semiconductor device 100 may include a first region A and a second region B disposed in a horizontal direction with respect to the first region. The second region B may include a peripheral circuit element 100B. The peripheral circuit element 100B may be formed through a series of processes combined with the process of forming the logic element 100A described above, and constituent components thereof may be related to each other. For example, the first source/drain patterns 130A may include a material the same as that of the first and second P-type epitaxial patterns 130A1 and 130A2, and the second source/drain patterns 130B may include a material the same as that of the first and second N-type epitaxial patterns 130B1 and 130B2.

FIGS. 4A to 4C are cross-sectional views of a second region B of the semiconductor device of FIG. 1, taken along III1-III1′, III2-III2′, and III3-III3′.

Referring to FIGS. 1 and 4A to 4C, the peripheral circuit element 100B of the semiconductor device 100 may include first and second active patterns 105A and 105B extending on a second region B of an insulating base layer 201 in a first direction (for example, a D1 direction), and an inactive gate structure NG crossing the first and second active patterns 105A and 105B in a second direction (for example, a D2 direction).

Referring to FIGS. 1, 4A and 4B, the peripheral circuit element 100B may include a first P-type epitaxial pattern 130A1 and a second P-type epitaxial pattern 130A2 respectively disposed on regions of the first active pattern 105A, on a first side and a second side of the inactive gate structure NG opposing each other, and a first N-type epitaxial pattern 130B1 and a second N-type epitaxial pattern 130B2 respectively disposed on regions of the second active pattern 105B, on the first side and the second side of the inactive gate structure NG.

Here, the inactive gate structure NG may have a structure similar to that of the gate structure GS of the logic element 100A in terms of structure. However, in terms of circuitry, the inactive gate structure NG may be understood as a dummy structure that is not connected to any interconnection line (for example, M1b) for voltage application and does not substantially contribute to operation of the logic element 110A (see FIG. 4C).

As described above, the inactive gate structure NG may have components similar to those of the gate structure GS of the logic element 100A, and respective corresponding components may include the same material.

Referring to FIG. 4C, the inactive gate structure NG may include a gate electrode 145 surrounding semiconductor patterns 125, a gate insulating film 142 between the semiconductor patterns 125 and the gate electrode 145, gate spacers 141 disposed on both sidewalls of a portion of the gate electrode 145 positioned on an uppermost semiconductor pattern, among the semiconductor patterns 125, and a gate capping layer 147 disposed on the gate electrode 145 between the gate spacers 141.

In some implementations, as illustrated in FIG. 4C, the peripheral circuit element 100B may include semiconductor patterns 125 respectively stacked on the first and second active patterns 105A and 105B to be spaced apart from each other in the third direction (for example, a D3 direction), or a vertical direction. The inactive gate structure NG may extend in the second direction (for example, a D2 direction), and may surround the semiconductor patterns 125. On both sides of the inactive gate structure NG, first and second P-type epitaxial patterns 130A1 and 130B2 may be respectively disposed on both side surfaces of the semiconductor patterns 125.

Referring to FIGS. 4A and 4B, the peripheral circuit element 100B may include a shared contact 180C connecting the first P-type epitaxial pattern 130A1 and the first N-type epitaxial pattern 130B1 to each other, on the first side of the inactive gate structure NG, and a first contact 180A2 and a second contact 180B respectively connected to the second P-type epitaxial pattern 130A2 and the second N-type epitaxial pattern 130B2, on the second side of the inactive gate structure NG.

The shared contact 180C may connect the first P-type epitaxial pattern 130A1 and the first N-type epitaxial pattern 130B1 to each other, on the first side of the inactive gate structure NG, and may not be connected to a first interconnection line M1b of a first interconnection structure 210 in a similar manner to the inactive gate structure NG. Each of the first and second contacts 180A and 180B may be connected to the first interconnection line M1b of the first interconnection structure 210 by a first via V1b, and thus may operate as a peripheral circuit element.

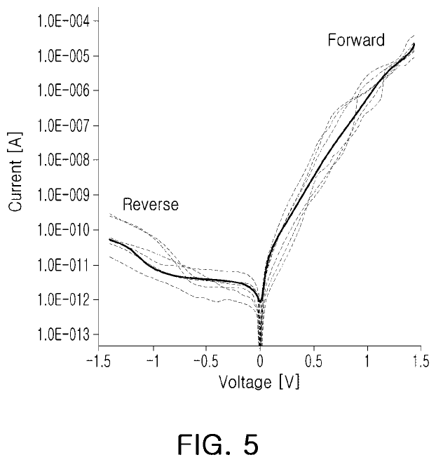

When a voltage is applied to the first and second contacts 180A and 180B, an element including the first P-type epitaxial pattern 130A1, the first N-type epitaxial pattern 130B1, and the shared contact 180C connecting the first P-type epitaxial pattern 130A1 and the first N-type epitaxial pattern 130B1 to each other may exhibit the IV characteristics illustrated in FIG. 5. Here, a dotted line may represent repeated results from various examples, and a solid line may represent a standardized result.

Referring to FIG. 5, under a forward voltage, current may increase according to an applied voltage. Under a reverse voltage, little current may flow (with only minor leakage current). Thus, behavior similar to that of a PN junction diode may be obtained.

Although the I-V characteristics shown in FIG. 5 are not as ideal as those of a typical PN junction diode, they are sufficient for use as diodes in peripheral circuit.

In particular, the peripheral circuit element 100B may be advantageously used as a PN junction diode for a peripheral circuit of the semiconductor device 100 by only changing contact structures (for example, 180A, 180B, and 180C) in a cell structure similar to that of the logic element 100A, without, in some implementations, an additional process requiring a mask.

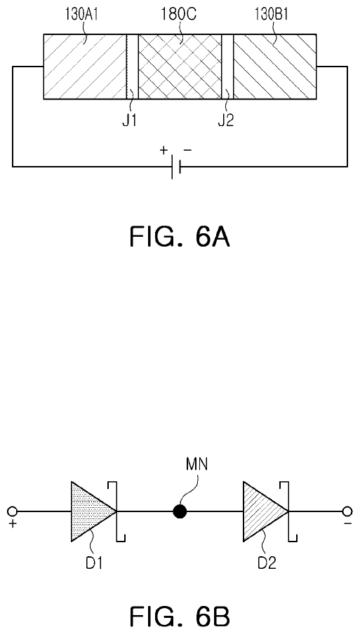

In the peripheral circuit element 100B (for example, as shown in FIG. 4A), as schematically illustrated in FIG. 6A, the shared contact 180C may be disposed between the first P-type epitaxial pattern 130A1 and the first N-type epitaxial pattern 130B1, and may form a first Schottky junction J1 with the first P-type epitaxial pattern 130A1 and a second Schottky junction J2 with the first N-type epitaxial pattern 130B1, and the first Schottky junction J1 and the second Schottky junction J2 may be connected to each other in series by the shared contact 180C. As illustrated in the equivalent circuit of FIG. 6B, two Schottky diodes D1 and D2 may be connected to each other by a connection node MN that is the shared contact 180C. In this aspect, the peripheral circuit element 100B may be referred to as a double Schottky junction element.

As confirmed in the IV characteristics of FIG. 5, the peripheral circuit element 100B may not exhibit ideal electrical characteristics corresponding to those of the general PN junction diode. However, the electrical characteristics of the peripheral circuit element 100B are such that the peripheral circuit element 100B may be used as a PN junction diode for a peripheral circuit in a semiconductor device from which a semiconductor substrate is structurally removed or otherwise not present. In addition, structures and impurity concentrations of the first P-type epitaxial pattern 130A1 and the first N-type epitaxial pattern 130B1, and a metal-semiconductor compound film 135 may be improved to adjust Schottky junction characteristics, thereby sufficiently securing desired electrical characteristics of the PN junction diode.

In some implementations, the peripheral circuit element 100B may be formed using a process substantially the same as that of the logic element 100A, as described above. Accordingly, the peripheral circuit element 100B may have a structural relationship with the logic element 100A. For example, the semiconductor patterns 125 of the peripheral circuit element 100B may be layers respectively formed using a process the same as that of the semiconductor patterns 125 of the logic element 100A. As described, the semiconductor patterns 125 of the two elements 100A and 100B may be positioned on the same level, and may include substantially the same semiconductor material. In addition, the first and second P-type epitaxial patterns 130A1 and 130A2 and the first and second N-type epitaxial patterns 130B1 and 130B2 may be formed using processes the same as or similar to those of the first and second source/drain patterns 130A and 130B of the logic element 100A. For example, the first and second P-type epitaxial patterns 130A1 and 130A2 may be formed together with the first source/drain patterns 130A. Similarly, the first and second N-type epitaxial patterns 130B1 and 130B2 may be formed together with the second source/drain patterns 130B. Epitaxial layers formed using the same process may have the same composition and impurity concentration. However, the device configuration is not limited thereto. In some implementations, the first and second P-type epitaxial patterns 130A1 and 130B2 and the first and second N-type epitaxial patterns 130B1 and 130B2 may be formed using processes different from those of the first and second source/drain patterns 130A and 130B of the logic element 100A.

In some implementations, an interlayer insulating layer 160 may be formed on the first surface of the insulating base layer 201 to cover the first and second P-type epitaxial patterns 130A1 and 130A2 and the first and second N-type epitaxial patterns 130B1 and 130B2. The interlayer insulating layer 160 may be disposed on the isolation layer 110. For example, the interlayer insulating layer 160 may include FOX, TOSZ, USG, BSG, PSG, BPSG, PETEOS, FSG, HDP oxide, PEOX, FCVD oxide, or combinations thereof. The interlayer insulating layer 160 may be formed using chemical vapor deposition, a fluid CVD process, or a spin coating process.

The semiconductor device 100 may further include the interlayer insulating layer 160 and an intermediate insulating layer 191 covering gate structures GS, DG, and NG. The intermediate insulating layer 191 may include an insulating material similar to that of the interlayer insulating layer 160.

Referring to FIGS. 2 and 3A, contacts 180′ of the logic element 100A may pass through the intermediate insulating layer 191 as well as the interlayer insulating layer 160, and may be respectively connected to the first and second source/drain patterns 130A and 130B. Similarly, referring to FIGS. 4A and 4B, the first and second contacts 180A and 180B and the shared contact 180C of the peripheral circuit element 100B may pass through the interlayer insulating layer 160 and the intermediate insulating layer 191, and may be respectively connected to the first and second P-type epitaxial patterns 130A1 and 130B2.

Conversely, referring to FIG. 3B, a gate contact 190 may pass through the intermediate insulating layer 191 and the gate capping layer 147, and may be connected to the gate electrode 145.

The contacts 180′ of the logic element 100A and the first and second contacts 180A and 180B and the shared contact 180C of the peripheral circuit element 100B may include a metal 185 and a conductive barrier 182 surrounding a side surface and a bottom surface of the metal 185. For example, the metal 185 may include Cu, Co, Mo, Ru, W, or alloys thereof. For example, the conductive barrier 182 may include Ta, TaN, Mn, MnN, WN, Ti, TiN, or combinations thereof. In some implementations, in order to improve contact resistance between the contacts 180', the first and second contacts 180A and 180B, and the shared contact 180C, the first and second source/drain patterns 130A and 130B, the first and second P-type epitaxial patterns 130A1 and 130B2, and the first and second N-type epitaxial patterns 130B1 and 130B2 may include a metal-semiconductor compound film 135. For example, the metal-semiconductor compound film 135 may include a metal silicide such as cobalt silicide (CoSiₓ), nickel silicide (NiSiₓ), or manganese silicide (MnSiₓ), but the material is not limited thereto. Referring to FIG. 3B, in a similar manner to the contacts 180', the gate contact 190 may include a metal 195 and a conductive barrier 192 surrounding a side surface and a bottom surface of the metal

### 195.

The semiconductor device 100 has a double-sided interconnection structure including an upper interconnection structure 210 and a lower interconnection structure 220. The double-sided interconnection structure may be present in both the first and second regions A and B, and may be configured to electrically connect the logic elements 100A and the peripheral circuit elements 100B to each other. The upper interconnection structure 210 may be provided on an upper surface of the semiconductor device 100, and the lower interconnection structure 220 may be provided on a lower surface of the semiconductor device 100.

In some implementations, the upper (or first) interconnection structure 210 may include a plurality of (for example, two) upper insulating layers 211, and first and second upper metal lines M1a and M1b and first and second upper vias V1a and V1b formed in the upper insulating layers 211. For example, respective interconnection layers (referring to combinations of metal lines and related vias) may be formed using a dual damascene process. An upper interconnection layer positioned in the first region A may include the first upper metal line M1a and the first upper vias V1a, and the upper interconnection layer positioned in the second region B may include the second upper metal line M1b and the second upper vias V1b. The upper interconnection layer may be configured such that the logic element 100A and the peripheral circuit element 100B are connected to each other.

An insulating protective film (or an etch stop film) 197 may be disposed on the second surface (or a lower surface) of the insulating base layer 201. The lower interconnection structure 220 may be disposed on the insulating protective film 197. The lower interconnection structure 220 may include a lower insulating layer 221 and first and second lower metal lines M2a and M2b formed in the lower insulating layer 221. The first lower metal line M2a may be provided as a power line connected to a conductive through-structure 170. The second lower metal line M2b may be provided as a signal line. In some implementations, the lower interconnection structure 220 positioned in the second region B may further include an additional interconnection layer, and may be configured such that the logic element 100A and the peripheral circuit element 100B are connected to each other in conjunction with the supply of the power line. In some implementations, the insulating protective film 197 and the upper and lower insulating layers 211 and 221 may include different insulating materials. For example, the insulating protective film 197 may include AlN or SiN, and the upper and lower insulating layers 211 and 221 may include SiO₂.

The semiconductor device 100 may be implemented in various modified examples. For example, at least one contact may be changed to have a backside contact structure passing through the insulating base layer 201, such that the peripheral circuit element 100B of the semiconductor device 100 may be implemented.

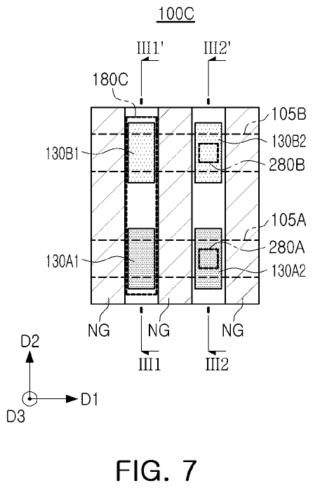

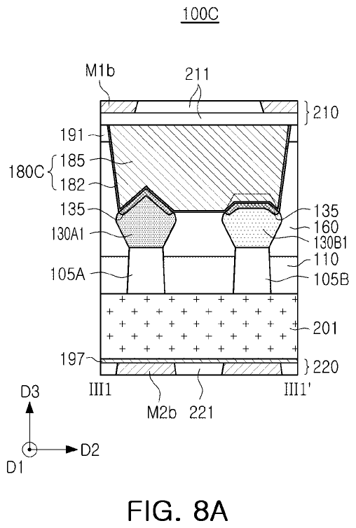

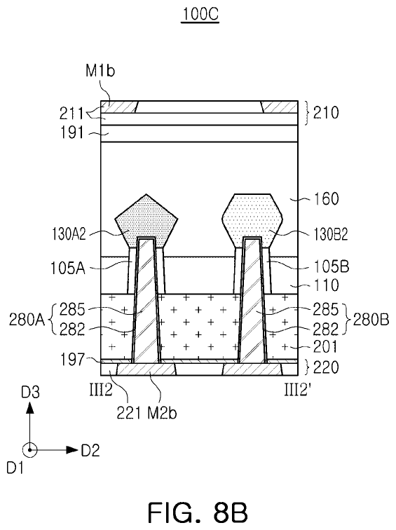

FIG. 7 is a plan view of a semiconductor device (in particular, a peripheral circuit element) according to some implementations of the present disclosure, and FIGS. 8A and 8B are cross-sectional views of the semiconductor device of FIG. 7, taken along III1-III1′ and III2-III2′.

Referring to FIGS. 7, 8A, and 8B, it may be understood that a peripheral circuit element 100C is similar to the peripheral circuit element 100B illustrated in FIGS. 1, 4A, 4B, and 4C, except that the peripheral circuit element 100C includes a first contact 280A and a second contact 280B having a backside contact structure passing through an insulating base layer 201. In addition, components of the peripheral circuit element 100C may be understood with reference to the descriptions of the same or similar components of the peripheral circuit element 100B illustrated in FIGS. 1, 4A, 4B, and 4C, unless otherwise stated.

In a similar manner to the peripheral circuit element 100B, the peripheral circuit element 100C may include a shared contact 180C passing through an interlayer insulating layer 160, the shared contact 180C connected to first P-type and N-type epitaxial patterns 130A1 and 130B1 in common (see FIG. 8A). However, the first contact 280A and the second contact 280B may have a backside contact structure.

Referring to FIGS. 7 and 8B, the first contact 280A may pass through a first active pattern 105A from a second surface of the insulating base layer 201, and may be connected to a second P-type epitaxial pattern 130A2. Similarly, the second contact 280B may pass through a second active pattern 105B from the second surface of the insulating base layer 201, and may be connected to a second N-type epitaxial pattern 130B2. The first and second contacts 280A and 280B may include a metal 285 and a conductive barrier 182 surrounding a side surface and an upper surface of the metal 285. To improve contact resistance with the first and second contacts 280A and 280B, the second P-type and N-type epitaxial patterns 130A2 and 130B2 may include a metal-semiconductor compound film (not illustrated). A second lower metal line M2b may be connected to the first and second contacts 280A and 280B.

In the peripheral circuit element 100C, it is illustrated that both the first contact 280A and the second contact 280B have a backside contact structure, but the contact configuration is not limited thereto. In some implementations, only one of the first contact 280A and the second contact 280B may have a backside contact structure, and an epitaxial pattern 130A2 or 130B2 of the other one may be connected to an upper contact structure similar to the shared contact 180C, and the upper contact structure may be connected to an upper interconnection structure 210.

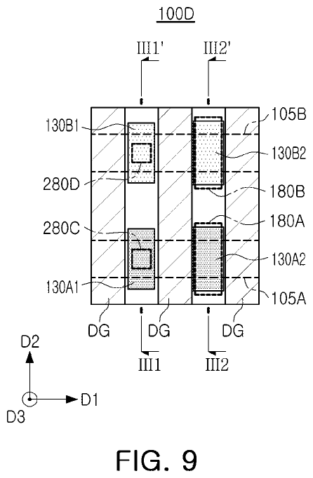

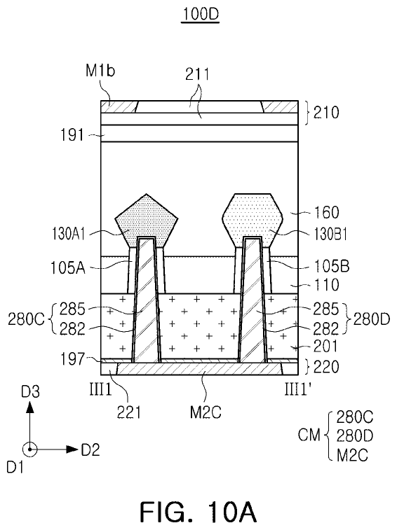

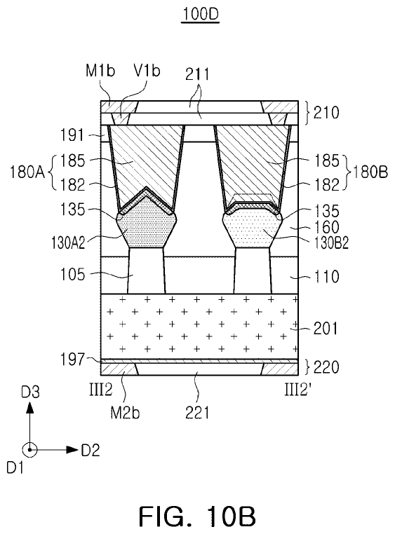

FIG. 9 is a plan view of an example of a semiconductor device (in particular, a peripheral circuit element) according to some implementations of the present disclosure, and FIGS. 10A and 10B are cross-sectional views of the semiconductor device of FIG. 9, taken along III1-III1′ and III2-III2′.

Referring to FIGS. 9, 10A, and 10B, it may be understood that a peripheral circuit element 100D is similar to the peripheral circuit element 100B illustrated in FIGS. 1, 4A, 4B, and 4C, except that the peripheral circuit element 100D has a shared contact CM having a backside contact structure passing through an insulating base layer 201. In addition, components of the peripheral circuit element 100D may be understood with reference to the descriptions of the same or similar components of the peripheral circuit element 100B illustrated in FIGS. 1, 4A, 4B, and 4C, unless otherwise stated.

In a similar manner to the peripheral circuit element 100B, the peripheral circuit element 100D may include first and second contacts 180A and 180B passing through an interlayer insulating layer 160, the first and second contacts 180A and 180B respectively connected to second P-type and N-type epitaxial patterns 130A2 and 130B2 (see FIG. 10B). However, the shared contact CM may have a backside contact structure.

Referring to FIGS. 9 and 10A, a common contact CM may include a third contact 280C and a fourth contact 280D having a backside contact structure, and a metal interconnection M2C connecting the third and fourth contacts 280C and 280D to each other.

For example, the third contact 280C may pass through a first active pattern 105A1 from a second surface of the insulating base layer 201, and may be connected to a first P-type epitaxial pattern 130A1, and the fourth contact 280D may pass through a second active pattern 105B from the second surface of the insulating base layer 201, and may be connected to a first N-type epitaxial pattern 130B1. The metal interconnection M2C may be provided on a lower interconnection structure 220 on the second surface of the insulating base layer 201. In some implementations, the metal interconnection M2C may be provided not as a power line or a signal line, but as a pattern connecting the third and fourth contacts 280C and 280D to each other.

In some implementations, the third and fourth contacts 280C and 280D may be connected to each other by the lower interconnection structure 220, but the contact configuration is not limited thereto. In some implementations, a buried connection portion (not illustrated) may be introduced into the insulating base layer 201 in place of the metal interconnection M2C. The buried connection portion may be formed in suitable backside contact processes.

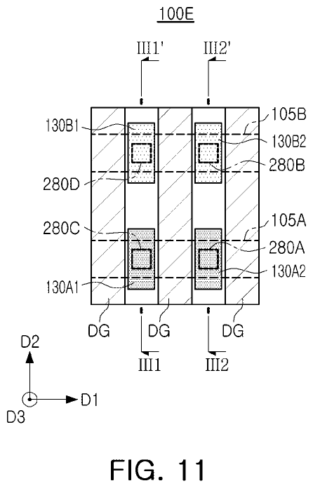

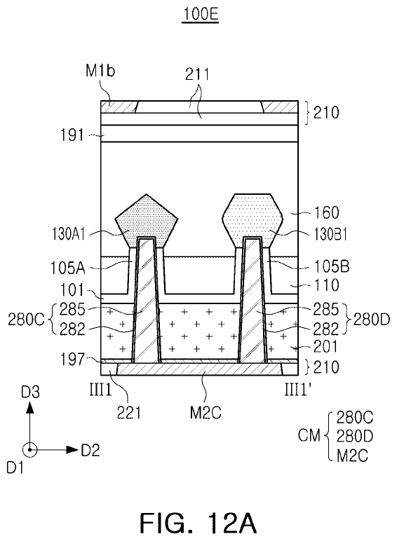

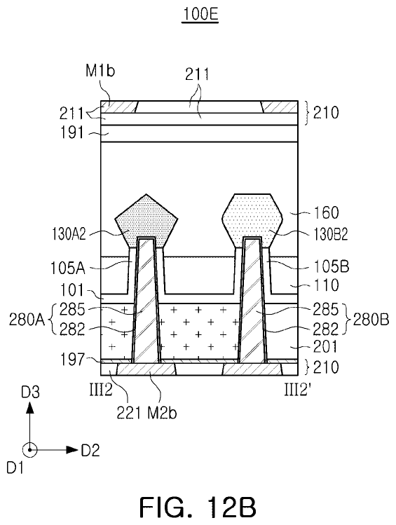

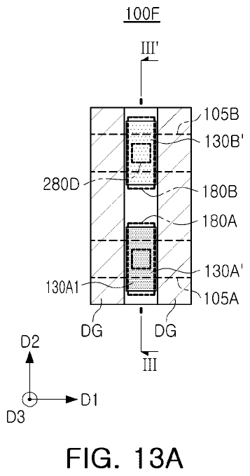

FIG. 11 is a plan view of an example of a semiconductor device (in particular, a peripheral circuit element) according to some implementations of the present disclosure, and FIGS. 12A and 12B are cross-sectional views of the semiconductor device of FIG. 11, taken along III1-III1′ and III2-III2′.

Referring to FIGS. 11, 12A, and 12B, it may be understood that a peripheral circuit element 100E is similar to the peripheral circuit element 100B illustrated in FIGS. 1, 4A, 4B, and 4C, except that the peripheral circuit element 100E includes a first contact 280A and a second contact 280B having a backside contact structure passing through an insulating base layer 201, and that the peripheral circuit element 100E has a shared contact CM having a backside contact structure passing through the insulating base layer 201. In addition, components of the peripheral circuit element 100E may be understood with reference to the descriptions of the same or similar components of the peripheral circuit element 100B illustrated in FIGS. 1, 4A, 4B, and 4C, unless otherwise stated.

In some implementations, all contact structures of the peripheral circuit element 100E may be provided as a backside contact structure.

Referring to FIG. 12A, the shared contact CM may include a third contact 280C and a fourth contact 280D having a backside contact structure, and a metal interconnection M2C connecting the third and fourth contacts 280C and 280D to each other. The third contact 280C may pass through a first active pattern 105A1 from a second surface of the insulating base layer 201, and may be connected to a first P-type epitaxial pattern 130A1, and the fourth contact 280D may pass through a second active pattern 105B from the second surface of the insulating base layer 201, and may be connected to a first N-type epitaxial pattern 130B1. In addition, the metal interconnection M2C, connecting the third and fourth contacts 280C and 280D to each other, may be provided on a lower interconnection structure 220 on the second surface of the insulating base layer 201.

Referring to FIG. 12B, the first contact 280A may pass through a first active pattern 105A from the second surface of the insulating base layer 201, and may be connected to a second P-type epitaxial pattern 130A2. Similarly, the second contact 280B may pass through a second active pattern 105B from the second surface of the insulating base layer 201, and may be connected to a second N-type epitaxial pattern 130B2.

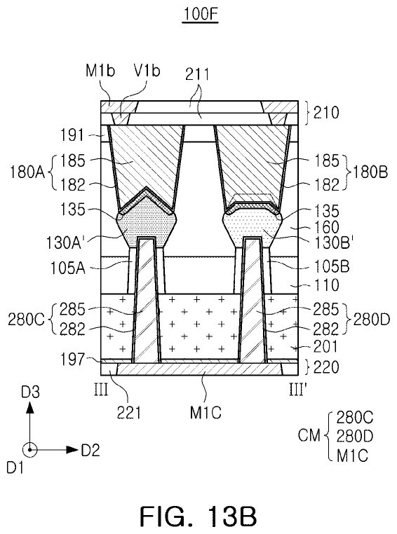

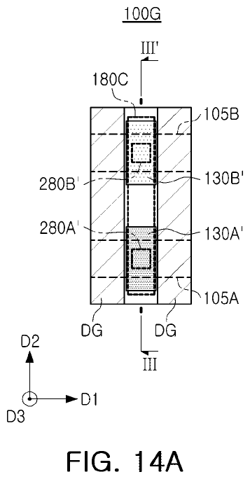

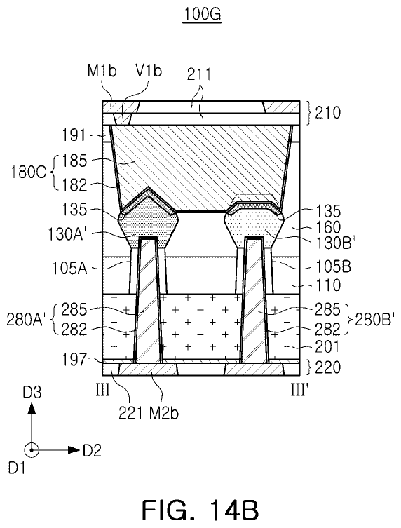

In the previously-described examples, epitaxial patterns for a double Schottky junction structure and epitaxial patterns for signal contact may be separately implemented. However, in some implementations, a pair of epitaxial patterns (for example, a single P-type epitaxial pattern and a single N-type epitaxial pattern) may be implemented by partially introducing a backside contact structure. Such examples are illustrated in FIGS. 13A and 13B, and in FIGS. 14A and 14B.

FIG. 13A is a plan view of an example of a semiconductor device according to some implementations of the present disclosure, and FIG. 13B is a cross-sectional view of the semiconductor device of FIG. 13A, taken along III1-III1′.

Referring to FIGS. 13A and 13B, it may be understood that a peripheral circuit element 100F is similar to the peripheral circuit element 100B illustrated in FIGS. 1, 4A, 4B, and 4C, except that the peripheral circuit element 100F includes a single P-type epitaxial pattern 130A′ and a single N-type epitaxial pattern 130B′, that first and second contacts 180A and 180B are respectively connected to upper surfaces of the P-type epitaxial pattern 130A′ and the N-type epitaxial pattern 130B′, and that a shared contact CM having a backside contact structure is connected to lower surfaces of the P-type epitaxial pattern 130A′ and the N-type epitaxial pattern 130B′ in common. In addition, components of the peripheral circuit element 100F may be understood with reference to the descriptions of the same or similar components of the peripheral circuit element 100B illustrated in FIGS. 1, 4A, 4B, and 4C, unless otherwise stated.

The peripheral circuit element 100F may include inactive gate structures DG, and a single P-type epitaxial pattern 130A′ and a single N-type epitaxial pattern 130B′ may be respectively disposed on first and second active patterns 105A and 105B between the inactive gate structures DG.

Referring to FIG. 13B, the first and second contacts 180A and 180B may pass through an interlayer insulating layer 160, and may be respectively connected to an upper surface of the P-type epitaxial pattern 130A′ and an upper surface of the N-type epitaxial pattern 130B′. Each of the first and second contacts 180A and 180B may be connected to an upper interconnection structure 210 through a first via V1b. Conversely, a common contact CM may be connected to lower surfaces of the P-type epitaxial pattern 130A′ and the N-type epitaxial pattern 130B′ in common. The shared contact CM may include a third contact 280C passing through a first active pattern 105A from a second surface of an insulating base layer 201, the third contact 280C connected to a lower surface of the P-type epitaxial pattern 130A', a fourth contact 280D passing through a second active pattern 105B from the second surface of the insulating base layer 201, the fourth contact 280D connected to a lower surface of the N-type epitaxial pattern 130B′, and a metal interconnection M1C connecting the third and fourth contacts 280C and 280D to each other on the second surface of the insulating base layer 201. In some implementations, the metal interconnection M1C may be provided not as a power line or a signal line, but as a pattern connecting the third and fourth contacts 280C and 280D to each other.

FIG. 14A is a plan view of an example of a semiconductor device according to some implementations of the present disclosure, and FIG. 14B is a cross-sectional view of the semiconductor device of FIG. 14A, taken along line III1-III1′.

Referring to FIGS. 14A and 14B, it may be understood that a peripheral circuit element 100G is similar to the peripheral circuit element 100B illustrated in FIGS. 1, 4A′, 4B′, and 4C, except that the peripheral circuit element 100G includes a single P-type epitaxial pattern 130A′ and a single N-type epitaxial pattern 130B′, that first and second contacts 280A′ and 280B′ having a backside contact structure are connected to lower surfaces of the P-type epitaxial pattern 130A′ and the N-type epitaxial pattern 130B′ in common, and that a shared contact 180C is connected to each of upper surfaces of the P-type epitaxial pattern 130A′ and the N-type epitaxial pattern 130B′. In addition, components of the peripheral circuit element 100G may be understood with reference to the descriptions of the same or similar components of the peripheral circuit element 100B illustrated in FIGS. 1, 4A, 4B, and 4C, unless otherwise stated.

In a similar manner to the example of FIGS. 13A and 13B, the peripheral circuit element 100G may include inactive gate structures DG, and a single P-type epitaxial pattern 130A′ and a single N-type epitaxial pattern 130B′ may be respectively disposed on first and second active patterns 105A and 105B between the inactive gate structures DG.

Referring to FIG. 14B, the first contact 280A′ may pass through a first active pattern 105A′ from a second surface of an insulating base layer 201, and may be connected to a lower surface of the P-type epitaxial pattern 130A′, and the second contact 280B′ may pass through a second active pattern 105B′ from the second surface of the insulating base layer 201, and may be connected to the N-type epitaxial pattern 130B′. The first and second contacts 280A′ and 280B′ may be respectively connected to second lower metal lines M2b. Conversely, the shared contact 180C may pass through the interlayer insulating layer 160, and may be connected to an upper surface of the P-type epitaxial pattern 130A′ and an upper surface of the N-type epitaxial pattern 130B′ in common. The shared contact 180C may be electrically separated from an upper interconnection structure 210.

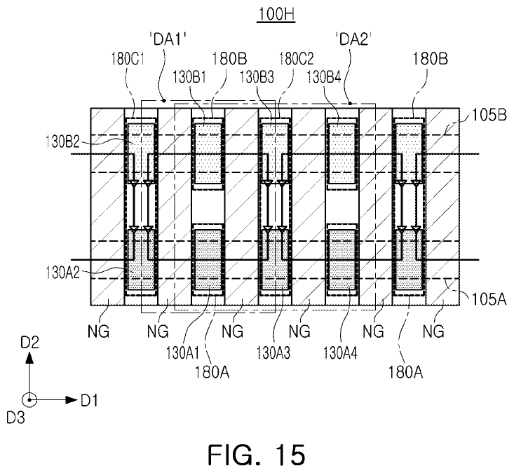

FIG. 15 is a plan view of an example of an array type semiconductor device according to some implementations of the present disclosure.

Referring to FIG. 15, a peripheral circuit element 100H may include an array structure in which the double Schottky junction elements of FIGS. 1 and 4A to 4C are arranged in a first direction (for example, a D1 direction).

The peripheral circuit element 100H may include first and second active patterns 105A and 105B respectively extending in the first direction (for example, a D1 direction), and inactive gate structures NG respectively extending in a second direction (for example, a D2 direction), respectively. P-type and N-type epitaxial patterns 130A and 130B may be respectively disposed on regions of first and second active patterns 105A and 105B between adjacent inactive gate structures NG.

In some implementations, odd-numbered P-type and N-type epitaxial patterns 130A and 130B may be connected to each other in the first direction (for example, D1 direction) by a shared contact 180C to provide a double Schottky junction structure. In addition, first and second contacts 180A and 180B may be respectively connected to even-numbered P-type and N-type epitaxial patterns 130A and 130B in the first direction (for example, D1 direction) to provide contacts for a double Schottky junction element.

In some implementations, the peripheral circuit element 100H may be separated into first and second array units DA1 and DA2 and implemented as individual elements.

The first array unit DA1 may include first P-type and N-type epitaxial patterns 130A1 and 130B1 between one sides of two inactive gate structures NG, second P-type and N-type epitaxial patterns 130A2 and 130B2 on the other side of one inactive gate structure NG, and third P-type and N-type epitaxial patterns 130A3 and 130B3 on the other side of the other inactive gate structure NG. The second P-type and N-type epitaxial patterns 130A2 and 130B2 and the third P-type and N-type epitaxial patterns 130A3 and 130B3 may be respectively connected to each other by shared contacts 180C1 and 180C2 to provide a pair of double Schottky junction structures. The first P-type and N-type epitaxial patterns 130A1 and 130B1 may be respectively connected to first and second contacts 180A and 180B. The first and second contacts 180A and 180B may be provided as a common contact for the pair of double Schottky junction structures.

The second array unit DA2 may include third P-type and N-type epitaxial patterns 130A3 and 130B3 between one sides of the two inactive gate structures NG, first P-type and N-type epitaxial patterns 130A1 and 130B1 on the other side of one inactive gate structure NG, and fourth P-type and N-type epitaxial patterns 130A4 and 130B4 on the other side of the other inactive gate structure NG. The third P-type and N-type epitaxial patterns 130A3 and 130B3 may be connected to each other by a shared contact 180C2 to provide a single double Schottky junction structure. The first P-type and N-type epitaxial patterns 130A1 and 130B1 and the fourth P-type and N-type epitaxial patterns 130A4 and 130B4 may be respectively connected to first and second contacts 180A and 180B. The single double Schottky junction structure may be shared by the first and second contacts 180A and 180B on both sides.

At least one of the first and second contacts 180A and 180B and the shared contacts 180C1 and 80C2 may be changed to have a backside contact structure passing through the insulating base layer 201, as described with reference to FIGS. 7 to 12B.

Accordingly, as described above, in some implementations, there may be provided a peripheral circuit element having an advantageous structure, the peripheral circuit element having improved electrical characteristics by changing only a contact structure in a structure of a logic element, in some implementations without requiring an additional process.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples have been illustrated and described above, it will be apparent to those skilled in the art that modifications and variations could be made without departing from the scope of the present disclosure.

What is claimed is:

1. A semiconductor device comprising:
an insulating base layer having a first surface and a second surface facing opposite to each other;
first and second active patterns extending in a first direction on the first surface of the insulating base layer;
an inactive gate structure crossing the first and second active patterns in a second direction, wherein the second direction intersects the first direction;
a first P-type epitaxial pattern and a second P-type epitaxial pattern on the first active pattern, on respective first and second sides of the inactive gate structure, wherein the first and second sides of the inactive gate structure are opposite sides of the inactive gate structure;
a first N-type epitaxial pattern and a second N-type epitaxial pattern on the second active pattern, respectively on the first and second sides of the inactive gate structure;
a shared contact connecting the first P-type epitaxial pattern and the first N-type epitaxial pattern; and
a first contact connected to the second P-type epitaxial pattern and a second contact connected to the second N-type epitaxial pattern.

2. The semiconductor device of claim 1, wherein:
the first contact connected to the second P-type epitaxial pattern extends through the first active pattern from the second surface of the insulating base layer, and
the second contact connected to the second N-type epitaxial pattern extends through the second active pattern from the second surface of the insulating base layer.

3. The semiconductor device of claim 2, wherein each of the first and second contacts includes:
a metal, and
a conductive barrier covering an upper surface and a side surface of the metal.

4. The semiconductor device of claim 1, wherein the shared contact includes:
a third contact connected to the first P-type epitaxial pattern and extending through the first active pattern from the second surface of the insulating base layer;
a fourth contact connected to the first N-type epitaxial pattern and extending through the second active pattern from the second surface of the insulating base layer; and
a metal interconnection on the second surface of the insulating base layer, the metal interconnection connecting the third and fourth contacts to each other.

5. The semiconductor device of claim 1, further comprising:
an interlayer insulating layer on the first surface of the insulating base layer, the interlayer insulating layer covering the first and second P-type epitaxial patterns and the first and second N-type epitaxial patterns.

6. The semiconductor device of claim 5, wherein:
the first contact is connected to the second P-type epitaxial pattern and extends through the interlayer insulating layer, and
the second contact is connected to the second N-type epitaxial pattern and extends through the interlayer insulating layer.

7. The semiconductor device of claim 5, wherein the shared contact extends through the interlayer insulating layer.

8. The semiconductor device of claim 1, further comprising:
a semiconductor layer connecting the first and second active patterns to each other, the semiconductor layer on the first surface of the insulating base layer.

9. The semiconductor device of claim 1, further comprising:
first semiconductor patterns on the first active pattern and spaced apart from each other in a vertical direction, and
second semiconductor patterns on the second active pattern and spaced apart from each other in the vertical direction.

10. The semiconductor device of claim 9, wherein the inactive gate structure includes:
a gate electrode surrounding each of the first and second semiconductor patterns, the gate electrode extending in the second direction, and
a gate insulating film between the first and second semiconductor patterns and the gate electrode.

11. A semiconductor device comprising:
an insulating base layer having a first surface and a second surface facing opposite to each other;
first and second active patterns extending in a first direction on the first surface of the insulating base layer;
first and second inactive gate structures crossing the first and second active patterns in a second direction, wherein the second direction intersects the first direction;
a P-type epitaxial pattern on the first active pattern, wherein the P-type epitaxial pattern is between the first and second inactive gate structures;
an N-type epitaxial pattern on the second active pattern, wherein the N-type epitaxial pattern is between the first and second inactive gate structures;
an interlayer insulating layer on the first surface of the insulating base layer, the interlayer insulating layer covering the P-type epitaxial pattern and the N-type epitaxial pattern;
a shared contact connecting the P-type epitaxial pattern and the N-type epitaxial pattern to each other, wherein the shared contact is between the first and second inactive gate structures;
a first contact connected to the P-type epitaxial pattern, wherein the first contact is between the first and second inactive gate structures; and
a second contact connected to the N-type epitaxial pattern, wherein the second contact is between the first and second inactive gate structures.

12. The semiconductor device of claim 11, wherein:
the first contact connected to the P-type epitaxial pattern extends through the first active pattern from the second surface of the insulating base layer,
the second contact connected to the N-type epitaxial pattern extends through the second active pattern from the second surface of the insulating base layer, and
the shared contact connected to the P-type epitaxial pattern and the N-type epitaxial pattern extends through the interlayer insulating layer.

13. The semiconductor device of claim 11, wherein:
the first contact connected to the P-type epitaxial pattern extends through the interlayer insulating layer,
the second contact connected to the N-type epitaxial pattern extends through the interlayer insulating layer, and
the shared contact includes:
a third contact connected to the P-type epitaxial pattern and extending through the first active pattern from the second surface of the insulating base layer,
a fourth contact connected to the N-type epitaxial pattern and extending through the second active pattern from the second surface of the insulating base layer, and
a metal interconnection on the second surface of the insulating base layer, the metal interconnection connecting the third and fourth contacts to each other.

14. A semiconductor device comprising:
an insulating base layer having a first surface and a second surface facing opposite to each other;
a first active pattern and a second active pattern extending in a first direction on the first surface of the insulating base layer;
a first inactive gate structure and a second inactive gate structure crossing the first and second active patterns in a second direction, wherein the second direction intersects the first direction;
a first P-type epitaxial pattern on the first active pattern and a first N-type epitaxial pattern on the second active pattern, wherein the first P-type epitaxial pattern and the first N-type epitaxial pattern are between the first inactive gate structure and the second inactive gate structure;
a second P-type epitaxial pattern on the first active pattern and a second N-type epitaxial pattern on the second active pattern, on a side of the first inactive gate structure opposite to a side of the first inactive gate structure on which the first P-type epitaxial pattern and the first N-type epitaxial pattern are arranged;
a third P-type epitaxial pattern on the first active pattern and a third N-type epitaxial pattern on the second active pattern, on a side of the second inactive gate structure opposite to a side of the second inactive gate structure on which the first P-type epitaxial pattern and the first N-type epitaxial pattern are arranged;
an interlayer insulating layer on the first surface of the insulating base layer, the interlayer insulating layer covering the first, second, and third P-type epitaxial patterns and the first, second, and third N-type epitaxial patterns;
a first contact and a second contact respectively connected to the first P-type epitaxial pattern and the first N-type epitaxial pattern;
a first shared contact connecting the second P-type epitaxial pattern and the second N-type epitaxial pattern to each other; and
a second shared contact connecting the third P-type epitaxial pattern and the third N-type epitaxial pattern to each other.

15. The semiconductor device of claim 14, wherein:
the first contact connected to the first P-type epitaxial pattern extends through the first active pattern from the second surface of the insulating base layer, and
the second contact connected to the first N-type epitaxial pattern extends through the second active pattern from the second surface of the insulating base layer.

16. The semiconductor device of claim 14, wherein the first shared contact includes:
a third contact connected to the second P-type epitaxial pattern and extending through the first active pattern from the second surface of the insulating base layer;
a fourth contact connected to the second N-type epitaxial pattern and extending through the second active pattern from the second surface of the insulating base layer; and
a first metal interconnection on the second surface of the insulating base layer, the first metal interconnection connecting the third and fourth contacts to each other.

17. The semiconductor device of claim 14, wherein the second shared contact includes:
a fifth contact connected to the third P-type epitaxial pattern and extending through the first active pattern from the second surface of the insulating base layer;
a sixth contact connected to the third N-type epitaxial pattern and extending through the second active pattern from the second surface of the insulating base layer; and
a second metal interconnection on the second surface of the insulating base layer, the second metal interconnection connecting the fifth and sixth contacts to each other.

18. The semiconductor device of claim 14, wherein:
the first contact connected to the first P-type epitaxial pattern extends through the interlayer insulating layer, and
the second contact connected to the first N-type epitaxial pattern extends through the interlayer insulating layer.

19. The semiconductor device of claim 14, wherein the first shared contact connected to the second P-type epitaxial pattern and the second N-type epitaxial pattern extends through the interlayer insulating layer.

20. The semiconductor device of claim 14, wherein the second shared contact connected to the third P-type epitaxial pattern and the third N-type epitaxial pattern extends through the interlayer insulating layer.
